(19) United States
(12) Patent Application Publication
(10) Pub. No.: US 2019/0378722 A1
(43) Pub. Date: Dec. 12, 2019

(54) SEMICONDUCTOR DEVICE WITH IMPROVED GATE-SOURCE/DRAIN METALLIZATION ISOLATION

(71) Applicant: GLOBALFOUNDRIES INC., GRAND CAYMAN (KY)

(72) Inventors: Laertis Economikos, Wappingers Falls, NY (US); Hui Zang, Guilderland, NY (US); Ruilong Xie, Schenectady, NY (US); Chanro Park, Clifton Park, NY (US)

(73) Assignee: GLOBALFOUNDRIES INC., GRAND CAYMAN (KY)

(21) Appl. No.: 16/002,207

(22) Filed: Jun. 7, 2018

(51) Int. Cl. H01L 21/28; H01L 29/66; H01L 21/768; H01L 29/78; H01L 29/49; H01L 23/535

(52) U.S. Cl. CPC H01L 21/28123; H01L 29/66795; H01L 21/28088; H01L 21/76805; H01L 21/76831; H01L 2221/1063; H01L 29/7851; H01L 29/4966; H01L 29/4983; H01L 23/535; H01L 21/76895

(57) ABSTRACT

A method of forming a semiconductor device such as a FinFET device includes forming a gate stack over a channel region of a semiconductor fin between spacer layers, recessing the gate stack and the spacer layers, and forming a gate conductor layer over both the recessed gate stack and the spacer layers. The gate conductor layer is adapted to inhibit etch damage to the spacer layers during a subsequent etching step used to form contact openings over source/drain regions of the fin. The resulting structure exhibits improved electrical isolation between gate and source/drain contacts.

### BACKGROUND

The present application relates generally to methods for forming semiconductor devices, and more specifically to methods for forming fin field effect transistors (FinFETs) having a reduced risk of electrical shorts between gate and source/drain contacts.

A trend in the development of semiconductor manufacturing technologies has been to increase the density of devices per chip, and hence decrease the size of active structures as well as the distances between such structures. An increase in device density may advantageously affect device performance such as circuit speed, and may allow also for increasingly complex designs and functionality. However, the decrease in size and the attendant increase in density may also generate undesirable effects, including unwanted short circuits between adjacent conductive elements.

In advanced node FinFET devices, the proximity of gate contacts and source/drain contacts may lead to unwanted parasitic capacitance or conduction, i.e., leakage, between these adjacent structures, particularly at the respective top and bottom portions of the structures. In comparative structures, for example, etching of an interlayer dielectric to form source/drain contact openings may result in unwanted erosion of an adjacent capping layer disposed over a functional gate, which may compromise dielectric isolation between the gate and later-formed source/drain metallization.

### SUMMARY

It is therefore desirable to develop semiconductor device architectures and methods for fabricating device architectures that have a decreased propensity for unwanted short circuits between adjacent conductive elements, such as between adjacent gate and source/drain contacts. As will be appreciated, although various embodiments are described herein with reference to a fin field effect transistor (FinFET), the semiconductor device may include a planar field effect transistor (FET) or nanowire FET, for example, although further device architectures are contemplated.

In conjunction with a replacement metal gate process, in accordance with various embodiments, a method of forming a device includes forming a gate stack over a channel region of a semiconductor fin between spacer layers, recessing the gate stack and the spacer layers, and forming a gate conductor layer over both the recessed gate stack and the spacer layers. The gate conductor layer is adapted to inhibit etch damage to the spacer layers during a subsequent etching step used to form contact openings over source/drain regions of the fin.

A sacrificial layer is deposited into the contact openings, which protects the source/drain regions of the fin during a recess etch of the gate conductor layer. A self-aligned capping layer is then formed over the recessed gate conductor layer. In particular embodiments, formation of the self-aligned capping layer is performed after an etching step to from the contact openings. The sacrificial layer is removed selectively with respect to the self-aligned capping layer, and a source/drain metallization layer and source/drain contact are formed over the source/drain regions of the fin.

In accordance with certain embodiments, a method of forming a semiconductor device includes forming source/drain junctions between spacer layers and over source/drain regions of a semiconductor layer, forming an interlayer dielectric over the source/drain junctions, and forming a gate stack over a channel region of the semiconductor layer between the source/drain regions. By way of example, the semiconductor layer may include a semiconductor fin.

The gate stack is recessed to a first height, and the spacer layers are recessed to a second height greater than the first height. Thereafter, a gate conductor layer is formed over the recessed gate stack and over the recessed spacer layers. The method further includes etching the interlayer dielectric selectively with respect to the gate conductor layer to form contact openings over the source/drain junctions.

According to further embodiments, a semiconductor device includes a gate stack having a gate dielectric layer and a work function metal layer disposed over a channel region of a semiconductor layer between source/drain regions, and a gate conductor layer disposed over the gate stack, wherein a top surface of the gate conductor layer is non-planar.

A further exemplary semiconductor device includes a gate stack having a gate dielectric layer and a work function metal layer disposed between spacer layers, and a gate conductor layer disposed over the gate stack, wherein a top surface of the gate conductor layer is non-planar.

### BRIEF DESCRIPTION OF SEVERAL VIEWS OF THE DRAWINGS

The following detailed description of specific embodiments of the present application can be best understood when read in conjunction with the following drawings, where like structure is indicated with like reference numerals and in which:

FIG. 1 is a cross-sectional schematic view of a FinFET device following the successive deposition of gate dielectric and work function metal layers between adjacent spacer layers and over channel regions of a semiconductor fin;

FIG. 2 shows the formation of a recessed masking layer over the gate dielectric and work function metal layers within the channel regions;

FIG. 3 depicts a recess etch of the gate dielectric and work function metal layers;

FIG. 4 shows a recess etch of the spacer layers;

FIG. 5 depicts the deposition of a gate conductor layer over the recessed work function metal and gate dielectric layers, and over a top surface of the recessed spacers layers;

FIG. 6 shows the formation of a masking layer and etching of an interlayer dielectric to create contact openings over source/drain regions of the fin;

FIG. 7 shows the deposition of a sacrificial layer within the contact openings;

FIG. 8 depicts a recess etch of the gate conductor layer;

FIG. 9 shows the formation of a self-aligned gate cap over the recessed gate conductor layer;

FIG. 10 depicts removal of the sacrificial layer from within the contact openings;

FIG. 11 shows the formation of a source/drain metallization layer within the contact openings and over the source/drain regions of the fin; and

FIG. 12 shows the formation of a contact level dielectric layer and source/drain contacts extending through the contact level dielectric layer.

### DETAILED DESCRIPTION

Reference will now be made in greater detail to various embodiments of the subject matter of the present application, some embodiments of which are illustrated in the accompanying drawings. The same reference numerals will be used throughout the drawings to refer to the same or similar parts.

Disclosed is a method of manufacturing a fin field effect transistor. The fin field effect transistor (FinFET) is an attractive transistor architecture because of the relative simplicity of its manufacture compared to other double gate devices. In various embodiments, the channel of the FinFET is a thin, raised strip or fin of semiconductor material, typically silicon. A transistor gate envelops the fin so that the channel is gated on both sides of the vertical portions of the fin, which provides gate control that is superior to a planar, single gate metal oxide semiconductor field effect transistor (MOSFET).

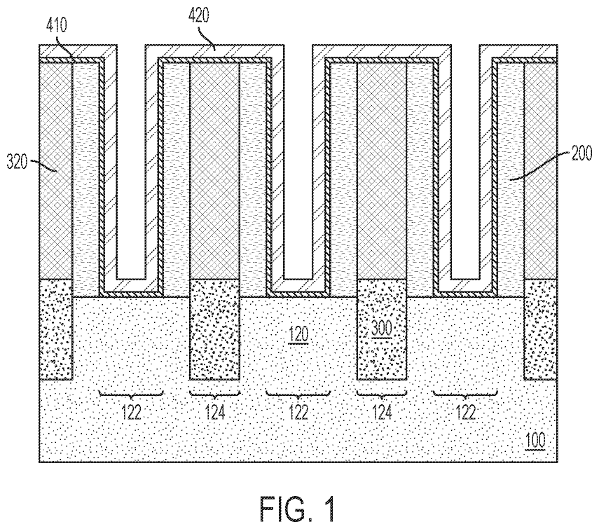

The manufacture of FinFETs typically leverages a self-aligned process to produce extremely thin fins, e.g., 20 nm wide or less, on the surface of a substrate using selective-etching techniques. A gate structure is then deposited to contact multiple surfaces of each fin to form a multi-gate architecture between source/drain regions of the fin. Respective conductive contacts are then formed to each of the gate and the source/drain regions. A method of forming a FinFET having robust isolation between the adjacent gate and source/drain contacts is described herein with reference to FIGS. 1-12.

Referring to FIG. 1, a semiconductor fin 120 is formed over a semiconductor substrate 100. The semiconductor substrate 100 may be a bulk substrate or a composite substrate such as a semiconductor-on-insulator (SOI) substrate, and may include any suitable semiconductor material as known to those skilled in the art. Portions of the semiconductor substrate may be amorphous, polycrystalline, or single crystalline. Although a single fin 120 is shown in the illustrated cross-section, it will be appreciated that an array of fins may be formed over the substrate 100.

In various embodiments, each fin 120 includes a semiconductor material such as silicon, and may be formed by patterning and then etching the semiconductor substrate 100, e.g., a top portion of the semiconductor substrate. In several embodiments, the fins 120 are etched from, and therefore contiguous with the semiconductor substrate 100. For instance, fin 120 may be formed using a sidewall image transfer (SIT) process as known to those skilled in the art.

Each fin 120 can include a single crystal semiconductor material that extends along a lengthwise direction. As used herein, a “lengthwise direction” is a horizontal direction along which an object extends the most. A “widthwise direction” is a horizontal direction that is perpendicular to the lengthwise direction.

As used here, “horizontal” refers to a general direction along a primary surface of a substrate, and “vertical” is a direction generally orthogonal thereto. Furthermore, “vertical” and “horizontal” are generally perpendicular directions relative to one another independent of orientation of the substrate in three-dimensional space.

In certain embodiments, the fin 120 can have a width of 5 nm to 20 nm, and a height of 40 nm to 150 nm, although other dimensions are contemplated. In structures including plural fins, i.e., a fin array, each fin may be spaced apart from its nearest neighbor by a periodicity or pitch (d) of 20 nm to 100 nm, e.g., 20, 30, 40, 50, 60, 70, 80, 90 or 100 nm, including ranges between any of the foregoing values. As used herein, the term “pitch” refers to the sum of the fin width and the spacing between neighboring fins.

Such plural fins are typically oriented parallel to each other and perpendicular to the library logic flow of a circuit. After fin formation, a fin cut or fin removal process may be used to eliminate unwanted fins or unwanted portions thereof for the particular circuit or device being fabricated. Thus, the fin-to-fin periodicity may be constant or variable over an array of fins.

Fin 120 includes alternating channel regions 122 and source/drain regions 124 as understood by one skilled in the art. Referring still to FIG. 1, illustrated is a replacement metal gate (RMG) structure following the removal of a sacrificial gate, showing spacer layers 200 that are formed over sidewalls of the sacrificial gate, source/drain junctions 300 disposed over source/drain regions 124 of the fin 120, and an interlayer dielectric and conformal liner (collectively 320) disposed over the source/drain junctions 300 between adjacent spacer layers 200. Following removal of the sacrificial gate, gate dielectric and work function metal layers 410, 420 are deposited in succession, i.e., between adjacent spacer layers 200 over the channel regions 122 of the fin 120.

Spacer layers 200 may be formed by blanket deposition of a spacer material (e.g., using atomic layer deposition) followed by a directional etch such as reactive ion etching (RIE) to remove the spacer material from horizontal surfaces. In certain embodiments, the spacer layer 200 thickness is 4 to 20 nm, e.g., 4, 10, 15 or 20 nm, including ranges between any of the foregoing values.

Source/drain junctions 300 may be formed by ion implantation or selective epitaxy following formation of the sacrificial gate and spacer layers 200, optionally using the sacrificial gates and spacer layers 200 as an alignment mask.

According to various embodiments, source/drain junctions 300 are formed by selective epitaxy into self-aligned cavities that are defined between the sacrificial gates. Source/drain junctions 300 may include silicon (e.g., Si) or a silicon-containing material such as silicon germanium (SiGe). For instance, SiGe source/drain junctions may be incorporated into a p-MOS device to provide compressive stress to the channel, which can improve carrier mobility.

As used herein, the terms “epitaxy,” “epitaxial” and/or “epitaxial growth and/or deposition” refer to the growth of a semiconductor material layer on a deposition surface of a semiconductor material, in which the semiconductor material layer being grown assumes the same crystalline habit as the semiconductor material of the deposition surface. For example, in an epitaxial deposition process, chemical reactants provided by source gases are controlled and the system parameters are set so that depositing atoms alight on the deposition surface and remain sufficiently mobile via surface diffusion to orient themselves according to the crystalline orientation of the atoms of the deposition surface. Therefore, an epitaxial semiconductor material has the same crystalline characteristics as the deposition surface on which it is formed. For example, an epitaxial semiconductor material deposited on a (100) crystal surface will take on a (100) orientation. Example epitaxial growth processes include low energy plasma deposition, liquid phase epitaxy, molecular beam epitaxy, and atmospheric pressure chemical vapor deposition.

The source/drain junctions 300 and corresponding (i.e., underlying) source/drain regions 124 of the fin 120 may be doped, which may be performed in situ, i.e., during epitaxial growth, or following epitaxial growth, for example, using ion implantation. Doping changes the electron and hole carrier concentrations of an intrinsic semiconductor at thermal equilibrium. A doped layer or region may be p-type or n-type.

As used herein, “p-type” refers to the addition of impurities to an intrinsic semiconductor that creates a deficiency of valence electrons. In a silicon-containing fin, example p-type dopants, i.e., impurities, include but are not limited to boron, aluminum, gallium, and indium. As used herein, “n-type” refers to the addition of impurities that contribute free electrons to an intrinsic semiconductor. In a silicon-containing fin, example n-type dopants, i.e., impurities, include but are not limited to, antimony, arsenic, and phosphorus.

After formation of the source/drain junctions 300, a conformal liner and an interlayer dielectric 320 (not separately shown) are successively formed within contact locations over the source/drain junctions 300, between neighboring spacer layers 200. The conformal liner is disposed over the spacer layers 200 as well as over a top surface of the source/drain junctions 300. The conformal liner is adapted to function as a contact etch stop layer (CESL).

Conformal liner may be formed by blanket deposition of a suitable contact etch stop material (e.g., using atomic layer deposition). In certain embodiments, the conformal liner thickness is 2 to 10 nm, e.g., 2, 4, 6, 8 or 10 nm, including ranges between any of the foregoing values.

Suitable spacer layer 200 and conformal liner materials include oxides, nitrides and oxynitrides, such as silicon dioxide, silicon nitride, silicon oxynitride, and low dielectric constant (low-k) materials such as amorphous carbon, SiOC, SiOCN and SiBCN, as well as a low-k dielectric material. As used herein, a low-k material has a dielectric constant less than that of silicon dioxide.

Exemplary low-k materials include but are not limited to, amorphous carbon, fluorine-doped oxides, or carbon-doped oxides. Commercially-available low-k dielectric products and materials include Dow Corning's SiLK™ and porous SiLK™, Applied Materials' Black Diamond™, Texas Instrument's Coral™ and TSMC's Black Diamond™ and Coral™.

In various embodiments, the spacer layer 200 and the conformal liner are formed from materials that can be etched selectively to one another. In particular embodiments, the spacer layer 200 includes SiOCN and the conformal liner (i.e., contact etch stop layer) includes silicon nitride.

Interlayer dielectric 320 is disposed between adjacent sacrificial gates, i.e., directly over the conformal liner. The interlayer dielectric 320 may include any dielectric material including, for example, oxides, nitrides or oxynitrides. In one embodiment, the interlayer dielectric 320 includes silicon dioxide. In various embodiments, the interlayer dielectric may be self-planarizing, or the top surface of the interlayer dielectric 320 can be planarized by chemical mechanical polishing (CMP) using the sacrificial gate as a polish stop.

“Planarization” is a material removal process that employs at least mechanical forces, such as frictional media, to produce a substantially two-dimensional surface. A planarization process may include chemical mechanical polishing (CMP) or grinding. Chemical mechanical polishing (CMP) is a material removal process that uses both chemical reactions and mechanical forces to remove material and planarize a surface.

Referring still to FIG. 1, a replacement metal gate (RMG) module includes removal of the sacrificial gate and the subsequent formation of a gate stack over the top and sidewall surfaces of the channel regions 122 of fin 120. The gate stack includes a conformal gate dielectric 410 formed directly over the exposed top and sidewall surfaces of the fin 120, and a work function metal layer 420 formed over the gate dielectric 410.

The gate dielectric 410 may include silicon dioxide, silicon nitride, silicon oxynitride, a high-k dielectric, or other suitable material. As used herein, a high-k material has a dielectric constant greater than that of silicon dioxide. A high-k dielectric may include a binary or ternary compound such as hafnium oxide (HfO₂). Further exemplary high-k dielectrics include, but are not limited to, ZrO₂, La₂O₃, Al₂O₃, TiO₂, SrTiO₃, BaTiO₃, LaAlO₃, Y₂O₃, HfOₓN_{y}, HfSiOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiOₓN_{y}, SiNₓ, a silicate thereof, and an alloy thereof. Each value of x may independently vary from 0.5 to 3, and each value of y may independently vary from 0 to 2. The gate dielectric thickness may range from 1 nm to 10 nm, e.g., 1, 2, 4, 6, 8 or 10 nm, including ranges between any of the foregoing.

The work function metal layer 420 may include a conductive material such as titanium carbide (TiC), titanium aluminide (TiAl), tantalum aluminide (TaAl₃), hafnium aluminide (HfAl or HfAl₃) or a metal silicide. The work function metal layer thickness may range from 2 nm to 12 nm, e.g., 2, 4, 6, 8, 10 or 12 nm, including ranges between any of the foregoing.

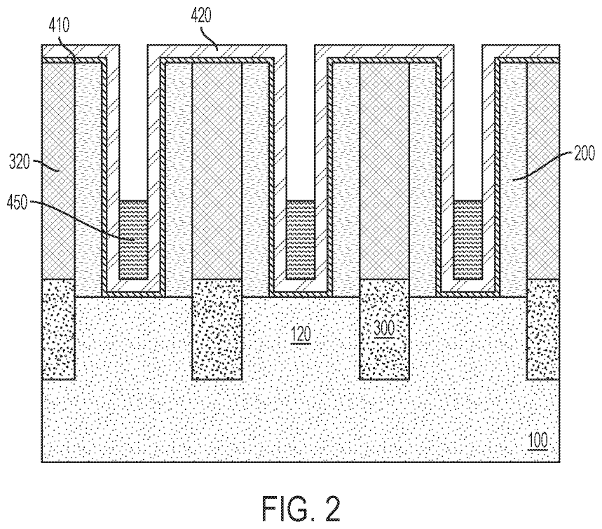

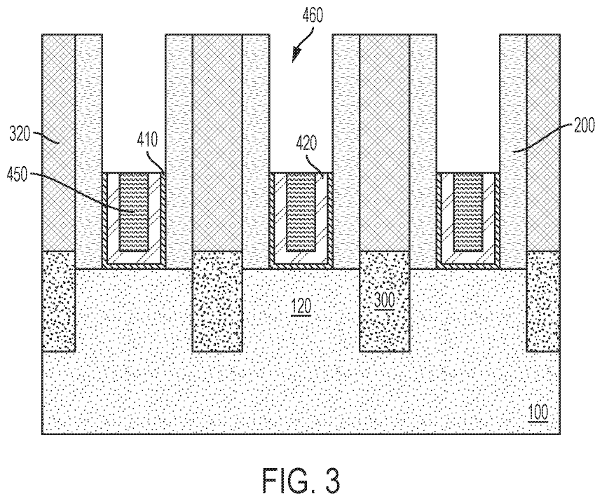

Referring to FIG. 2, a masking layer 450 is formed over the gate dielectric and work function metal layers, i.e., directly over the work function metal layer 420 over channel regions of the fin. The masking layer 450 is then recessed. Masking layer 450 may include an organic planarization layer (OPL) as known to those skilled in the art. As seen with reference to FIG. 3, masking layer 450 is adapted to limit the extent of a subsequent recess etch of the gate dielectric and work function metal layers 410, 420 to form gate openings 460 over channel regions of the fin 120.

According to various embodiments, masking layer 450 may include a photo-sensitive organic polymer that, when exposed to electromagnetic radiation, is chemically altered and thus configured to be removed using a developing solvent. For instance, a photo-sensitive organic polymer may be include a polyacrylate resin, epoxy resin, phenol resin, polyamide resin, polyimide resin, unsaturated polyester resin, polyphenylenether resin, polyphenylenesulfide resin, or benzocyclobutene.

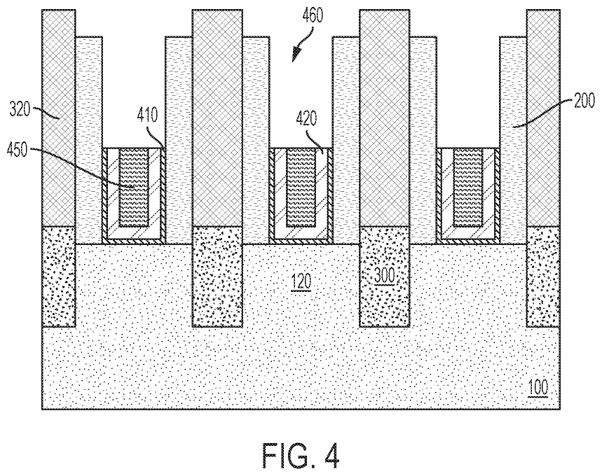

Referring to FIG. 4, a recess etch of the spacer layers 200 follows the recess etch of the gate dielectric and work function metal layers 410, 420. A pull-down etch of the spacer layers 200 exposes sidewalls of the interlayer dielectric 320. Following the recess etch of the spacer layers 200 and the recess etch of the gate dielectric and work function metal layers 410, 420, a top surface of the spacer layers 200 is above a top surface of the gate dielectric and work function metal layers 410, 420. The recess etching processes described herein typically include an anisotropic etch. In certain embodiments, a dry etching process such as, for example, reactive ion etching can be used. In other embodiments, a wet chemical etchant can be used. In still further embodiments, a combination of dry etching and wet etching can be used.

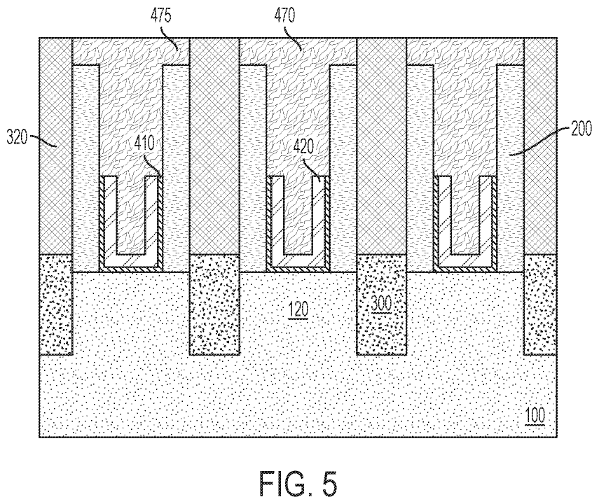

Referring to FIG. 5, a gate conductor layer 470 is formed over the recessed work function metal and gate dielectric layers 410, 420, as well as over a top surface of the recessed spacer layers 200. That is, a portion 475 of the gate conductor layer 470 extends laterally over the recessed spacer layers 200. A polishing step may be used to planarize the structure.

In various embodiments, the gate conductor 470 may include a conductive material such as polysilicon, silicon-germanium, a conductive metal such as Al, W, Cu, Ti, Ta, W, Co, Pt, Ag, Au, Ru, Ir, Rh and Re, as well as alloys of conductive metals, e.g., Al—Cu. In certain embodiments, the gate conductor layer 470 includes a titanium nitride (TiN) layer directly over the work function metal layer 420, and a tungsten or cobalt fill layer over the titanium nitride layer. The gate conductor layer 470, including laterally extending portion 475, is configured to protect the spacer layers 200 from erosion during subsequent etching steps.

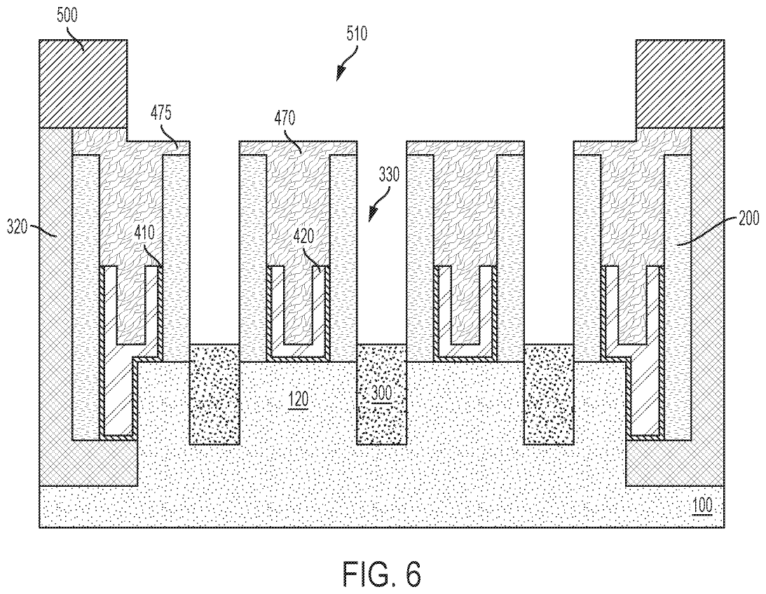

Referring to FIG. 6, a mask layer 500 is formed over the structure of FIG. 5. Using conventional photolithography, for example, opening 510 is formed in the mask layer 500 and exposed portions of the ILD layer 320 and contact etch stop layer within opening 510 are thereafter removed to form contact openings 330 over source/drain junctions 300. According to various embodiments, laterally-extending portions 475 of gate conductor layer 470 inhibit or prevent erosion of spacer layers 200 during etching of the ILD layer 320 and contact etch stop layer.

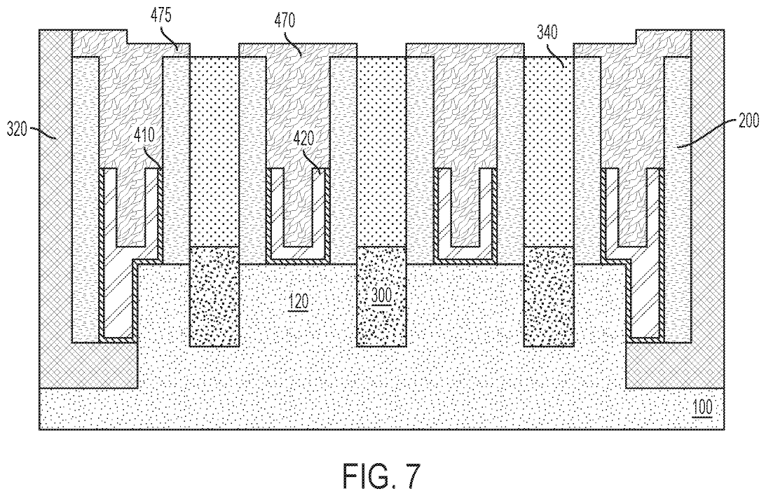

FIG. 7 shows the deposition of a sacrificial layer 340 within contact openings 330 directly over source/drain junctions 300. In certain embodiments, sacrificial layer 340 completely fills the contact openings 330 and is adapted to protect the source/drain junctions 300 during a subsequent recess etch of the gate conductor layer 470. Sacrificial layer 340 may include may include an organic planarization layer (OPL), for example, as described in connection with masking layer 450.

As shown in the illustrated embodiment, sacrificial layer 340 is recessed such that a top surface thereof is disposed below a top surface of the gate conductor layer 470. At this stage of processing, the mask layer 500 is also removed, i.e., during the recess etch of the sacrificial layer 340, and the laterally-extending portion 475 of the gate conductor layer 470 extends over a top surface of spacer layer 200.

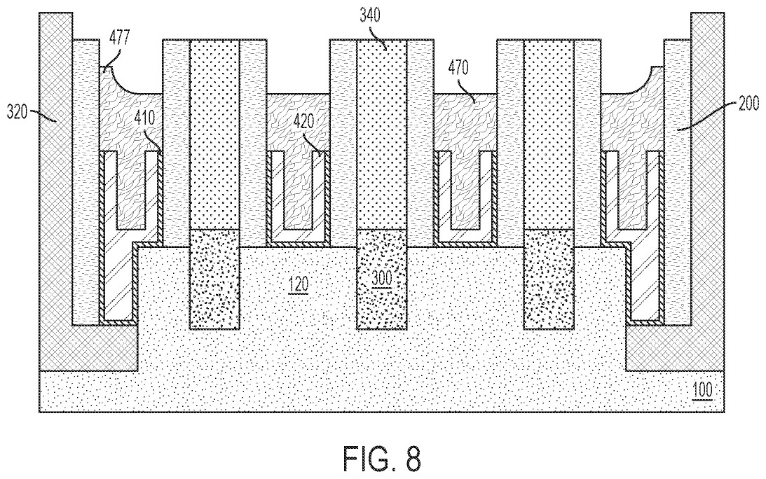

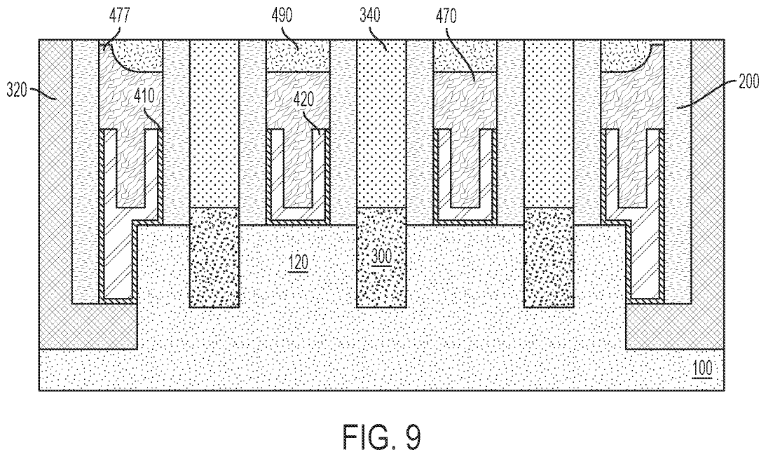

Referring to FIGS. 8 and 9, the gate conductor layer 470 is etched selectively with respect to spacer layer 200 and sacrificial layer 340 to form openings that are backfilled to form a gate cap 490. For instance, a reactive ion etch step can be used to recess the gate conductor layer 470. In certain embodiments, 25% to 75% of the original gate conductor layer height is removed by the recess etch.

With particular reference to FIG. 8, an upper region of the gate conductor layer 470 may be chamfered to include an upwardly-protruding portion 477 such that a top surface of the etched gate conductor layer 470 is substantially non-planar. That is, upwardly-protruding portion 477 of the etched gate conductor layer 470 corresponds to the portion of the gate conductor layer 470 that underlies mask layer 500 prior to forming sacrificial layer 340. In the illustrated embodiment, upwardly-protruding portion 477 is laterally displaced from an end of fin 120.

Turning to FIG. 9, the gate cap 490 may include a nitride material such as silicon nitride or silicon oxynitride (SiON). Following deposition of the gate cap 490, a further planarization process may be used to remove the overburden and, as shown in FIG. 9, complete the replacement metal gate module and form a planarized structure.

In certain embodiments, in the planarized structure, a top surface of the gate cap 490 and respective top surfaces of the sacrificial layer 340 and spacer layers 200 are mutually co-planar. As will be appreciated, the gate cap 490 overlies an entire top surface of the gate conductor layer 470, although the gate cap 490 may have a variable thickness.

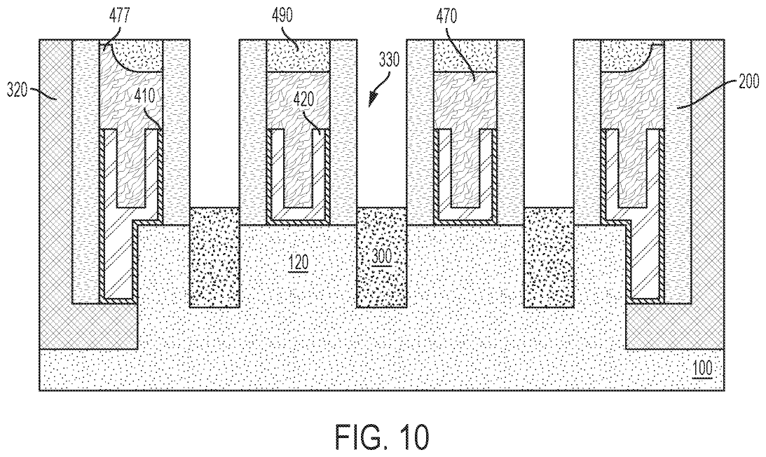

Referring to FIG. 10, the sacrificial layer 340 can be removed from over source/drain junctions 300 to form self-aligned contact openings 330. Removal of the sacrificial layer 340 can be performed using an etch that is selective to the adjacent, exposed layers. For instance, the sacrificial layer 340 can be removed by ashing, a reactive ion etch or isotropic etch such as a wet etch or an isotropic plasma etch.

Prior to metallization of the source/drain region, a wet etch can be used to remove native oxide from over the source/drain junctions 300. An example wet etch for stripping oxide includes hydrofluoric acid or a solution that includes dilute hydrofluoric acid (d-HF).

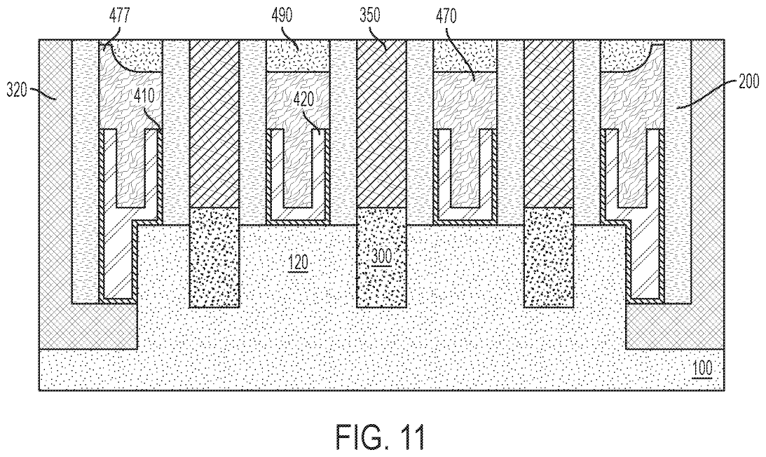

As shown in FIG. 11, conductive contacts 350 are formed within the contact openings 330 and over exposed surfaces of the source/drain junctions 300 by depositing, for example, a conductive liner and a barrier layer (not separately shown) and then filling the contact openings with a contact layer such as tungsten or cobalt. The conductive liner is typically titanium and the barrier layer may be titanium nitride (TiN).

Conductive contacts 350 may include a metal that forms an ohmic contact with the source/drain junctions 300. A silicide layer (e.g., titanium silicide) may be formed in situ via reaction between the conductive liner (e.g., titanium) and the source/drain junctions 300 to form a trench silicide contact.

After formation of the conductive contacts 350, a planarization process may be used to form a structure where top surfaces of conductive contacts 350 are co-planar with a top surface of the neighboring gate caps 490.

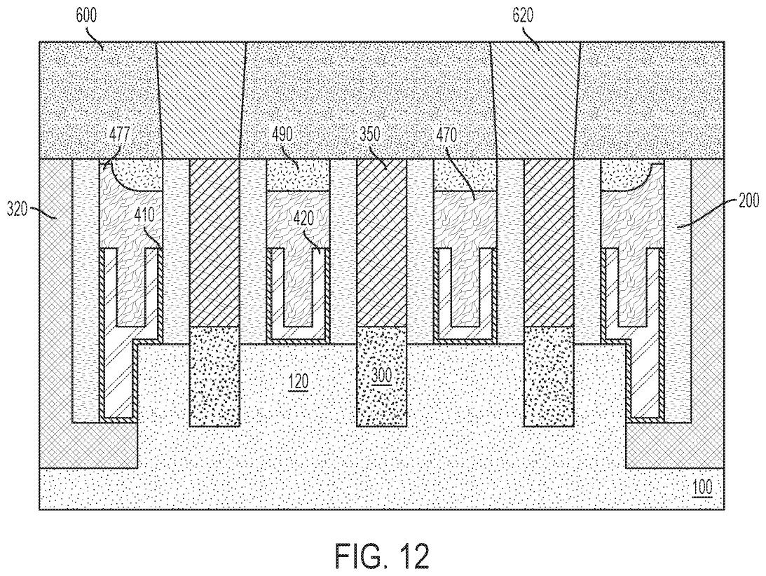

Additional processing may be used to form a functional device, including middle-of-the line and back-of-the line metallization and interconnect modules to form suitable electrical connections. As shown in FIG. 12, for instance, an interlayer dielectric 600 may be formed over the gate caps 490 and the conductive contacts 350. Conventional photolithography, etching and deposition processes may be used to form metal interconnects 620 within openings in the interlayer dielectric 600 and in electrical contact with conductive contacts 350.

As disclosed herein, a method of forming a FinFET device includes forming a gate stack over a channel region of a semiconductor fin between spacer layers, recessing the gate stack and the spacer layers, and forming a gate conductor layer over both the recessed gate stack and the spacer layers. The gate conductor layer is adapted to inhibit etch damage to the spacer layers during a subsequent etching step used to form contact openings over source/drain regions of the fin. The resulting structure exhibits improved electrical isolation between gate and source/drain contacts.

Unless the context indicates otherwise, materials and material layers may be formed or deposited by any suitable technique including, but not limited to, chemical vapor deposition (CVD), physical vapor deposition (PVD), atomic layer deposition (ALD), spin-on coating, etc. Alternatively, material layers may be formed in situ such as by thermal oxidation.

As used herein, the singular forms “a,” “an” and “the” include plural referents unless the context clearly dictates otherwise. Thus, for example, reference to a “fin” includes examples having two or more such “fins” unless the context clearly indicates otherwise.

It is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

It will be understood that when an element such as a layer, region or substrate is referred to as being formed on, deposited on, or disposed “on” or “over” another element, it can be directly on the other element or intervening elements may also be present. In contrast, when an element is referred to as being “directly on” or “directly over” another element, no intervening elements are present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a fin that comprises a semiconductor material include embodiments where a fin consists essentially of a semiconductor material and embodiments where a fin consists of a semiconductor material.

It will be apparent to those skilled in the art that various modifications and variations can be made to the present invention without departing from the spirit and scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

1-8. (canceled)

9. A semiconductor device, comprising:
a gate stack comprising a gate dielectric layer and a work function metal layer disposed over a channel region of a semiconductor layer; and
a gate conductor layer disposed over the gate stack, wherein a top surface of the gate conductor layer is non-planar.

10. The semiconductor device of claim 9, wherein the top surface of the gate conductor layer comprises an upwardly-protruding portion.

11. The semiconductor device of claim 10, wherein the semiconductor device is a FinFET, the semiconductor layer comprises a semiconductor fin and the upwardly-protruding portion is laterally displaced from an end of the semiconductor fin.

12. The semiconductor device of claim 9, further comprising a gate cap disposed directly over the top surface of the gate conductor layer.

13. The semiconductor device of claim 12, wherein the gate cap has a variable thickness.

14. The semiconductor device of claim 12, wherein the gate cap comprises silicon nitride.

15. The semiconductor device of claim 9, wherein the gate conductor layer comprises a layer of titanium nitride disposed directly over the work function metal layer.

16. A semiconductor device, comprising:
a gate stack comprising a gate dielectric layer and a work function metal layer disposed between spacer layers; and
a gate conductor layer disposed over the gate stack, wherein a top surface of the gate conductor layer is non-planar.

17. The semiconductor device of claim 16, further comprising a gate cap disposed directly over the top surface of the gate conductor layer.

18. The semiconductor device of claim 17, wherein a top surface of the gate cap is co-planar with a top surface of the spacer layers.
